(19) United States
(12) Patent Application Publication
(10) Pub. No.: US 2013/0313687 A1
(43) Pub. Date: Nov. 28, 2013

(54) Through via/the buried via elrctrolde material and the said via structure and the said via manufacturing method

(71) Applicant: ZyCube Co., Ltd., Kanagawa (JP)

(72) Inventors: Manabu Bonkohara, Kanagawa (JP); Hirofumi Nakamura, Kanagawa (JP); Qiwei He, Kanagawa (JP)

(73) Assignee: ZyCube Co., Ltd., Kanagawa (JP)

(21) Appl. No.: 13/740,688

(22) Filed: Jan. 14, 2013

(30) Foreign Application Priority Data
Jan. 13, 2012 (JP) 2012-005698

(51) Int. Cl. H01L 23/538; H01L 21/768

(52) U.S. Cl. CPC H01L 23/5384; H01L 21/76856
USPC 257/621; 438/658

(57) ABSTRACT

[Aim of Invention]

Providing the effective semiconductor miniaturization and its higher-dense fine wiring with the through-hole and the buried via electrode structure of the lower resistivity and higher reliability material at the low cost manufacturing method.
[Solution]
Preparing the sedimentation layer 57 buried at first the dried-sintered-porous metal material of paste 56 in the through-hole 51 having a insulation layer 54 on the board structure 50, fully covered over the porous area top of the sedimentation layer 57 with the second metal paste and then full-filling the second metal into the porous area of the sedimentation layer 57.

### BACKGROUND OF THE INVENTION

This invention relates to the structure (it is said with the through via/the buried via electrode material and its structure as follows) of the through hole via electrode which is suitable for the three-dimensional stacking of the semiconductor chip or the buried via electrode and the said manufacturing method.

### BACKGROUND ART

The demand of the highest integration of the silicon integrated circuit does not stop the semiconductor engineering progress on its background.

To promote high integration, there is a method that you can miniaturize the size of the unit element (transistor), increasing the chip size.

However, the development of new manufacturing technology associated with miniaturization requires enormous resources. Inspection and design of large-scale circuit with the chip size increase is also becoming more complex. In addition, the length of the signal transmission line becomes longer according to the chip size increasing, and then causes the circuit speed-up limitation.

As a method for forming an electrode on the opening via of the wafer substrate (semiconductor wafer substrate) required for the three-dimensional stacking of semiconductor chips, the following three conventional methods have been known generally. However, there remains some practical problem because of the following difficulties.

To eliminate these drawbacks, the structure stacked in the height direction and a plurality of chips, i.e., three-dimensional structure has been proposed. In this configuration, the signal line can be formed in the vertical direction at the central region of the up-ward chip and down-ward chip.

In this configuration, there is no need to stretch the signal transmission line to the chip peripheral area and connect one to another chip. As this result, high-speed signal transmission can be realized easily.

In order to realize such a “signaling line in the vertical direction”, the front and back surfaces of the chip electric connecting through-via electrode (Through Via) (as referred to TSV, a Through Silicon Via in the case of a silicon substrate) is used. And in the initial process this vertical signal line forms the buried electrode structure embedded without through hole, or forms the through electrode structure by shaving the bottom of the embedded portion by etching or grinding from the rear surface, then forms a connection between the internal circuitry remained and embedded said electrodes.

And such a through-via electrode is not only disposed in the central region of the chip and also arranged in chip peripheral some area (an area where electrical connections, referred to as “bonding pads” are arranged in the conventional configuration).

It is possible to produce the through via/the buried via electrode material and such electrode structure by preparing the following process (1) embedding of one surface near or through the front and back surfaces of chips, (2) forming an insulating layer on the sidewall of the hole, (3) filling a conductive material in the holes or depositing some conductive material on the side wall of the said chip electrodes, (4) fabricating an electrode pattern on the exposed electrode of the front and back surfaces of the said chip through via/buried via electrode material and such electrode structure.

As the forming process of the said through via/the buried via electrode material and such electrode structure described in paragraph (3), such many forming methods are known.

For example, the first method is a conformal copper plating method.

(1) A wet forming process method: There is such a representative example method using “the conformal copper plating method”. Thin and uniform Cu (copper) film layer are formed at the inside-wall of the electrode of the through-hole via embedding (Through-hole via/buried electrode and its electrode structure are formed fully filled). The big voids or hole left inside of the through-hole via/buried electrode and its electrode structure, has some treatment as (i) embedding with some epoxy resin or some polyimide resin, (ii) coating with a thin film of epoxy resin or polyimide resin on the surface of the copper thin film, (iii) no-covering with anything and not filled in via hole room.

In either case, cracks (breakage of the film layer) is likely to occur at the peripheral region of the through-hole via/buried electrode and its electrode structure exposed on the substrate surface. (the interface region between the substrate and the through-hole via/buried electrode embedded in particular).

Cracks induce the breakage of the electric wiring, and reduce reliability. In order to prevent crack generation, the conductive pattern that is larger than the diameter of the embedded electrode embedded through/(so-called a “land”) should be placed on the through-hole via/embedded electrode portion on the substrate surface, and in some cases used as a connection protection unit.

This method is a technique used for mass production, but is difficult for high-density interconnects since there is an opening on one side of the electrode and organization elements (lands, for example) positioned in the peripheral area of the through-hole via/embedded electrode become larger.

(2) dry method: This is a a method for filling the through hole with metal particles by using a sputtering equipment, ionization sputtering equipment or metal CVD equipment device or ionization sputtering apparatus, but the plating time may take longer.

There is a drawback that the manufacturing equipment is a high price, and that the filling time is long. Therefore, electrodes formed become high manufacturing cost. Further, since the electrode is formed by a dense metal layer, there is a possibility that excessive internal stress is generated due to the difference in the thermal expansion coefficient of the substrate, thereby damaging the substrate.

Furthermore, the high possibility of lowering the reliability of the electronic circuit is caused by leakage current generated in the cracking portion. Furthermore, since the electrodes are formed in a dense copper by “plating”, for example, when compared with the silicon wafer substrate, the thermal expansion coefficient difference is large, the elastic modulus is large, an excessive internal stress generated by the temperature cycle subsequent step there is also the potential to, causes cracks in the silicon wafer substrate.

The second method is a filling process.

FIG. 4 is a diagram listed in FIG. 1 of Patent Document 1. In the figure, 101 is a substrate having a through-hole 102, and is disposed on top of the filter 140. 130 is a (liquid was suspended purely fine metal particles) dispersion. By depressing the piston 120, 130 is pushed into the through hole. After dried take out the substrate 101, and filling the through hole inside the conductive paste.

That is, the conductive paste flows into between fine particles of gold.

When curing the conductive paste under a predetermined condition subsequently, the through electrode is formed. In this method, the conductivity of the through-electrode is ensured by the fine gold and conductive particles contained in the conductive paste. However, this conductive paste printing method is processed in the vacuumed ambient with a diluent monomer, the organic residues is large and the conductive resistivity (called the conductivity or the volume resistivity) of the conductive paste relatively large, ie this paste electrode has the disadvantage that there is some limitation to the high-speed signal transmission and the high current acceptability by this paste higher resistivity.

Further, if there is a difference in thermal expansion coefficient between the through electrode and the substrate 101, there is also a disadvantage of deteriorating long-term reliability and heat resistance. Therefore, the circuit design can be limited, leading to the occurrence of improper or poor electrical properties.

The third method is a filling type copper plating method.

FIG. 5 is a diagram listed in FIG. 1 of Patent Document 2. In the figure, applying a metal paste on the surface of the substrate having a through hole, is moved while vibrating the blade vibration generator, which is filled in the through hole of the metal paste. By the sintering at high temperature metal paste, through-electrode is formed. According to this method, increasing the conductivity of the through electrode is possible, but there is a drawback cracks may occur in the through electrode, and degrade the substrate itself by sintering conditions.

As mentioned above, many improved ideas of the three methods disclosed can be applied to the production of through-hole via/embedded electrode. However, there tends to conflict with the conductivity of the electrode, and deterioration of long-term reliability and heat resistance due to the difference in thermal expansion coefficient. That is, using the metal material to enhance the conductivity, the difference in thermal expansion coefficient is a factor of performance degradation. Even if there is a difference in thermal expansion coefficient, flexible materials (for example, conductive paste) absorb the stresses, reducing the signal transmission characteristic by conductivity deterioration.

For example, Patent Document 1, a method of depositing suspension of the metal powder on the opening hole by the filter and pressure is disclosed.

In Patent Document 2, a method of using a blade and was applied while applying vibration to the metal paste, in addition to a suction pressure from the opposite side of the wafer substrate at a time, to sinter by depositing the through hole of the paste is disclosed are.

In Patent Document 3, a method after applying the metal paste a small amount, it flows through the molten metal by the addition of high-speed vibration and heat in a vacuum environment, it is deposited is disclosed.

### PRIOR ART

### Patent Documents

| | | | |
|---|---|---|---|
| JP | 2011-54907 | A | March 2011 |
| JP | 2011-71153 | A | April 2011 |
| JP | 2009-277927 | A | November 2009 |

### SUMMARY OF THE INVENTION

### Problems to be Resolved by the Invention

In the method of Patent Documents 1 to 3, the purpose of each of which claims has been achieved, but considering the damage machining process is applied to an existing circuit pattern, desorption auxiliary material (supporting glass substrate, etc.), and all steps of the implementation of the semiconductor device in a comprehensive way, there is a hindrance to practical use.

This invention was performed considering above circumstances, and aims to provide low resistance and high reliability through-hole/embedded electrode that is locatable in higher density according to finer semiconductor manufacturing technologies, and a method to fabricate the electrode at a lower cost.

Another object of the present invention not specified herein will become apparent from the following description and the accompanying drawings.

### Means for Solving the Problems

Through-hole via/embedded electrode structure of the present invention, first porous formed by being subjected to a heat treatment after filling the first conductive material into the hole at least one disposed on the first main surface of the plate-like structure and one conductor, and a second conductive material consisting of a second conductive material to penetrate the cavity of the first conductor,

The second conductive material is characterized in that it is different from the first conductive material.

In the configuration of the through-hole/embedded electrode, preventing both deterioration of reliability due to the difference in thermal expansion coefficient, and the deterioration of the signal transfer characteristics due to conductivity less has become an issue.

Further, it is due to the miniaturization of semiconductor manufacturing technology, to place through hole/embedded electrode in a high density is demanded.

Therefore, even when reducing the size of the through-hole/embedded electrode techniques to ensure the reliability of the signal transfer characteristics, and further development of a method to fabricate the through-hole/embedded electrode is facilitated is obtained.

In order to achieve the above object, in the present invention, the physical properties of the filling material (electrode material) in the opening hole, and the processing time required and filling means are paid attentions.

The most important performance requirements for electrodes are conductivity. In order to achieve the required performance, a relatively large metal conductivity eliminate a cavity in the electrode and a large organic matter in resistivity.

Among metal particles, particles the alloy, metal compounds or semiconductor particles or the conductive particles are coated dissimilar member to member of inorganic or organic, wherein the first conductive material is composed of at least one.

Among metal particles, particles of the alloy, particles of the metal compound, semiconductor particles, or the particles of the organic member, the above second conductive material consists of at least one. The second conductive material is different from the first conductive material.

And the term “plate-like structure” is a circuit board and a semiconductor wafer. Through holes in the former has a function to electrically connect to each other, electric wiring pattern on the front and back surfaces of a single wafer, it has become a major component of the three-dimensional integrated circuits.

The through-hole in the later, is to achieve an electrical connection between the front and back surfaces of the circuit board. Such circuit boards is referred to as “interposer”, the material of which is silicone resin, and ceramic etc.

And the “through-hole” is exposed to the first main surface which is one of the front and back of the “plate-like structure.” In some cases, it is exposed to the second main surface which is a surface of the other of the two sides of the “plate-like structure”, but is not limited to this.

The shape of the “through-hole” is often cylindrical, but is not limited thereto. In addition, or area of the cross section of the through-hole, the diameter may be various settings when it is cylindrical.

Inner wall of through-hole is desirable to be insulating, and in case that the plate-like structure is conductive (e.g. a silicon wafer), it is necessary to deposit the insulating layer on the inner wall surface. Further, if the structure of the plate is composed of ceramic or resin, a new insulating layer is not necessary.

The term “first conductive material” means a material which is composed of at least one among metal particles, particles of the alloy, semiconductor particles or metal compound, and the conductive particles dissimilar material is coated member of inorganic or organic.

By the heat treatment after filling into the holes with “paste or solution” containing the first conductive material, wherein a porous “first conductive member” is obtained.

In addition, the method of filling a “paste, solution etc.” as described in the preceding paragraph is described. The method for flowing the fluid to hole portion, there is a well-known example of many.

For example, in the case of solution of which viscosity is low, ink jet nozzles (so-called a “jet dispenser”) and a micropipette is used.

Alternatively, it is filled by applying a vacuum atmosphere to a second main surface by spin coating to the first major surface. Sometimes facilitate filling by applying (e.g., air) pressure from the first main surface side. Sometimes it is allowed to settle the “conductive member” in solution and filled into the hole.

On the other hand, if the paste viscosity is large, a screen printing is used. The method can be applied either, but it is important to note, such as the prevention of voids and increase the fill rate is higher.

In addition, to reduce the thermal stress by the temperature cycle in the subsequent step, occurring between the electrode and the semiconductor substrate, the porous sintered body is characterized in that in proportion to the porosity, strength and elastic modulus rapidly decreased the material is an electrode configuration to.

Here, the “heat treatment” is explained. (For example, 0.1 μm or less) or, if the said first conductive material is observed (e.g., 0.3˜10 μm) micro-particles as a large plurality of ultrafine particles are bonded by static electricity ultrafine particles. When the solvent is evaporated by heat-treating the “paste or solution” containing fine particles, only the first conductive material remains.

If the heat treatment temperature is set lower than the melting point of the first conductive material, the shape of the conductive material (which is a form of fine particles) is not changed (=not melt). Whereby by such a heat treatment to “sinter” the first conductive material

Gap is present between the particles in the sintered body, and porous. The size of the gap is dependent upon the size of the fine particles, and surface shape. It means that infiltrate the second conductive material mentioned above into the gap.

In addition, some changes, but we focus on showing the mechanical properties of the porous sintered body generally, and aggregate the porous sintered body of the first metal having a high melting point relatively to it the impregnant is also a low melting by impregnating the second metal to form an electrode.

It has been described to obtain a sintered body in the “solvent evaporation” in the previous paragraph, but will now be described another example to obtain a sintered body. The coated with a material having a low melting point the surface of the first conductive material (which is particulate), is filled into the hole portion of the first conductive material that is processed into paste.

Then, by heat treatment, solvent of the paste is evaporated, and further, the material covering the first conductive material is melted, sintered porous as the first conductive material is obtained. The combination example of the dressing and take conductive material, there is something like the following.

First conductive material (“core part”): tungsten

Covering member (“skin portion”): At least one of indium, tin, copper, precious metals, (gold, silver, and platinum) of

In order to increase the (the difficulty peeling of the skin portion) coating strength and “core portion” and “skin portion” and “core portion” surface, a combination of two or at least one of “nickel, titanium, tantalum sometimes providing a coating layer consisting of”, is coated with the coating material on it.

This configuration is an example of a “conductive particles dissimilar material is coated on the inorganic member.” The illustrated tungsten here, it is not limited thereto.

In another example to obtain a sintered body, by a tungsten as first conductive material, and then filled into the hole this heat treatment is performed in a hydrogen atmosphere, the sintered body is obtained. Melting point of tungsten alone is as high as 3400° C., but it is used the fact that the melting point is lowered by treatment with hydrogen atmosphere. This technique not to use the liquid is “dry.”

Furthermore, by a tungsten as first conductive material to a paste with a solution containing a reducing agent, lowering the melting point is also possible. Or, “acid COOH system” said carboxylic acid and formic acid, a wax and rosin (pine resin). Examples of the reducing agent. It becomes a process of “wet” this technique because it requires the paste by the solvent. The illustrated tungsten in this paragraph, but is not limited thereto.

The term “second conductive material”, is a material which is made of at least one among metal particles, the alloy particles of the metal compound particles, the semiconductor particles or a material of the particles of the organic member having electrical conductivity it is not less, and is different from the first conductive material. That is, a combination of the first conductive material and the second conductive material is made of the same material is eliminated. The “second conductive member” is obtained by the process of heat treatment or the like from infiltrating into the gap formed in the first conductive member, to “paste or solution” containing the second conductive material.

If the melting point of the second conductive member is low, even to obtain a second conductor by infiltrating into the gap second conductive material that has been melted (in solution form) and cooled.

The term “organic material having an electrical conductivity” as described above, and that the material itself has electrical conductivity, and those obtained by mixing a conductive material in the organic material, the surface of the organic material there is also such as those conductive by coating the dissimilar material such as metal.

Examples of the conductive material mentioned above, there is something like the following.

Metal: tungsten, molybdenum, chromium, indium, tin, gold, silver

Alloy: indium-based alloy, tin-based alloy (tin-silver, gold-tin etc.), bismuth alloy (tin-bismuth etc.), gallium-based alloy, zinc alloy, nickel-cobalt, gold cobalt, solder kind metal alloy

Metal compound: ratio of species (constituent material because we compound that component the metal “mixed”)

Semiconductors of silicon, germanium, a compound semiconductor, silicon carbide, carbon

Particles plated metal indium, gold, silver, platinum, and tin on the surface of the fine particles such as a resin material: conductive particles are coated dissimilar member to member in organic.

Conductive particles heterogeneous member is coated member of inorganic: silicon carbide particulate silicon pa thin film coated, such as germanium (semiconductors) conductive thin film is coated, carbon-based material, diamond silicon nitride particulate material like conductive thin film is coated, aluminum nitride, borosilicate glass, boron nitride ceramic, or tungsten.

As a material for covering the fine particles, indium, indium alloys, nickel-gold, gold, silver, Some copper, platinum, tin, titanium, and tantalum.

In case of selecting these ered to ensure (1) for good reliability, thermal expansion coefficient difference between the plate-like structure is small, (2) for a better signal transfer characteristic, (resistance is small) conductivity is large and others.

Or bottom of the hole at least one (1) disposed on the first main surface is a surface of one of the front and back of the plate-like structure to place the conductors on the bottom surface of the hole at least one (2) a second conductive material which is permeated with the first conductive porous formed by being heat-treated and, after filling the first conductive material into the hole where the conductor is disposed, in the void of the first conductor Let me be through electrode and a second conductor in the configuration.

Note that the “hole portion where conductor is disposed on the bottom surface” mentioned above, it may also be all of a plurality of holes disposed on the first major surface. The “conductor disposed on the bottom surface” may also be a hole in a part of the plurality of holes.

Then, the specific structure of the “hole conductor is disposed on the bottom” is explained. In the following, an example a plate-like structure which an integrated circuit is created on the second main surface of the silicon wafer is assumed. Number of transistors are made up of the gate electrode (source and drain) of the diffusion layer is disposed (for convenience of explanation, a back surface) on the second main surface of a silicon integrated circuit.

The above-mentioned gate electrode, and the electrical wiring from the diffusion layer is embedded in the (oxide film, for example) insulating film.

The electrical wiring is extended to connection terminals located around the chip to (bonding pad). It is through electrode derive the (surface) side of the first major surface of the wafer (the electrical wiring) or the connection terminals. The process of making such a through electrode will be exemplified.

(1) The digging a hole toward the connection terminal (1) on the first main surface side. More specifically, (a position opposed to the connection terminal) position of the silicon substrate and formed a hole by using a technique such as (using the gas such as CIF3, BrF3, F2) reactive ion etching more to. Silicon substrate is completely removed in this technique, a state in which the insulating film is exposed at the bottom of the hole. Then, by performing reactive ion etching in an atmosphere of an acid such as (HF) gas fluoride, to remove the insulating film is exposed, to expose the surface of the connection terminal. The exposed surface is the first main surface side of the silicon substrate. As a result, the created “hole portion” is a structure disposed connection terminal (which is the “conductor”) on the bottom.

(2) An insulating film such as an oxide film covers the side wall (2) of the “hole.” Here, a technique chemical vapor deposition (CVD) and thermal oxidation is used. However, the insulating film is not attached to (the surface of the connection terminal exposed) the bottom surface of the “hole” is required. If, in the process of the coating, when the insulating film is also formed on the bottom surface, it is necessary to remove in a manner known this insulating film.

(3) Making the first conductor by having a in the bottom “hole” is filled with “paste or solution” of the first conductive material, heat-treating it. Result of this step, the first conductor is a sintered body (structure with a minute voids therein) porous.

(4) To produce a second conductive material by a gap a first conductor, is allowed to penetrate to “paste or solution” consisting of the second conductive material, and performs processing such as heat treatment.

The process described above, it becomes the configuration inside the first conductive porous second conductive member such as a “penetrating through” through electrode is created.

Then, the “electrical wiring” is explained. In silicon integrated circuits often a plurality of layers “Electrical Wiring” has been adopted. That is, the insulating film in a plurality of “Electrical Wiring” are arranged in the thickness direction, if necessary, interconnecting electrical wiring layer “interlayer wiring” is applied.

In such a configuration, placing the through-hole electrode for electric wiring desired layer is also possible. For example, to form a hole is dug in the silicon substrate electrical wiring layer of the second layer is exposed. In this case, a deeper hole than the position the electrical wiring layer of the first layer is disposed.

In the above description, it was through-hole electrode to (a second layer in the above example) electric wiring layers specified desired, but form a “hole” common for electric wiring layers, and wherein by making the through electrodes, it is possible to achieve both of the electric wiring layers between such multiple “interlayer wiring.”

The first conductor is assumed that its coefficient of thermal expansion does not exceed three times the thermal expansion coefficient of the plate-like structure.

There is a restriction of the coefficient of thermal expansion as a “first conductor” and “second conductor”. This restriction is necessary because when it is exposed to high temperature atmosphere, an internal stress caused by thermal expansion coefficient of the conductive material and the plate-like structure and the plate-like structure is not broken.

In particular, as described in the preceding paragraph, “thermal expansion coefficient that does not exceed three times” is required for the “first conductive member”. If the plate-like structure is silicon, such material example will be listed as follows.

(1) tungsten, molybdenum, and chrome
(2) (Silicon, germanium etc.) semiconductor particulate conductive thin film is coated Silicon carbide particulate
(3) a conductive thin film is coated, carbon-based material, diamond-like material
(4) Silicon nitride particulate the conductive thin film is coated, aluminum nitride, borosilicate glass, and boron nitride ceramics

In general, the coefficient of thermal expansion of the metal is about 10 times larger than the thermal expansion coefficient of the silicon wafer, this difference becomes the cause of corruption, leading to difficulties to ensure high reliability.

By employing “does not exceed three times” material, it is possible to reduce the internal stress. The selection of the material is performed even if the plate-like structure is composed of a (ceramic or plastic) materials other than silicon.

Melting point of the second conductive material, a value not exceeding 300° C.

Metal particles, particles of the alloy particles of the metal compound, semiconductor particles, or the “second conductive member” is comprised of a second conductive material consisting of particles of organic member having electrical conductivity. The second conductive material, should be composed of a conductive material having a melting point value does not exceed 300° C. is preferred. Alternatively the heat resistance, the structure of the substrate or plate, in the case where multiple devices are integrated structure of the plate is a silicon wafer, constraints such temperature than the highest temperature in the integration step by lower temperature processing. Examples of such material is a metal or like tin and indium, and (metal mixture consisting of 17.3% tin, bismuth 57.5%, from 25.2% indium) solder, but it is not limited thereto.

Volume of the second conductor is a value that does not exceed the volume of the first conductor.

The volume of the first conductor, should be greater than the volume of the second conductive body. Depends on the material chosen, but in general, while the thermal expansion coefficient is small, the first conductor is higher thermal conductivity. Further, while a low melting point, the second conductor is lower thermal conductivity. As the focus of the present invention is the difference in thermal expansion coefficient between device substrate with these conductive materials for the elimination of reliability degradation, so the increasing of the heat scattering effect by increasing the thermal conductivity is preferred for this purpose. Such reasons, thereby increasing the heat scattering effect by giving a difference in the volume of these conductors.

The volume of the first conductor, should be greater than the volume of the second conductive body. Depends on the material chosen, but in general, the first conductor is smaller volume resistivity, a second conductor larger volume resistivity. This present invention main purpose is the elimination of the deterioration of the signal transfer characteristics by increasing the conductivity of the through hole via electrode, it is preferable to use a lot of material having a low volume resistivity. By this reason, it increases the conductivity of said conductive material by giving a difference in the volume of the conductor.

To illustrate the preferred combination of the second conductor and the first conductor, which is as follows. It is based on the guidelines to achieve a conductivity greater second conductive body (second conductive material), a small thermal expansion coefficient of the first conductor in the (first conductive material).

The first conductive material: the metal particles made of particles such as tungsten, (Surface may be conductive covering by indium or indium alloy)(heterogeneous member is coated member of (=inorganic coated with metal particles).

Indium alloy or indium: the second conductive material

This combination is an example, it not to be limited to this.

A step of producing a hole of at least one the first main surface is a surface of one of the two sides of (1) plate-like structure, a step of depositing an insulating layer on the inner wall (2) of the hole, (particles of three) metal particles, alloy particles, or the semiconductor particles or metal compounds, a first conductive material consisting of at least one of the conductive particles dissimilar material is coated member of inorganic or organic a step of said first conductive material by heat-treating a step of filling the hole to “paste or solution” and “paste or solution” (4) the first conductive material, the particles (5) metal, particles of alloy particles of the metal compound, semiconductor particles, or the first conductive member to “paste or solution” a second conductive material consisting of at least one of the particles of the organic member having electrical conductivity a step for the second conductive material by heat-treating the step of infiltrating the gap, ‘Paste or solution “(6) the second conductive material, the first or the first main surface (7) of the plate-like structure Alternatively two main surfaces, to produce a through electrode in the process of smoothing the second major surface of the first main surface.

Step described above in (2) becomes unnecessary when the substrate or plate-like structure is composed of a ceramic or resin. Further, steps (3) and (4), but may be performed a plurality of times in this combination.

Such repeated process has the effect of increasing the deposition amount of the first conductor. Further, the above step (5) and (6) may be carried out repeatedly several times in this combination. Such repeating process has the effect of increasing the penetration amount of the second conductor.

There may be many forms in step (3) mentioned above, which has no limitatiom to that particular component “or paste solution”.

For example, a liquid viscous material as the paste is a diluent of high volatility solvent less residue was prepared metal particles having a large conductive having a particle size of several 100 nanometers from several 10 microns. It should be noted that the processing residue material, which is an impurity when configured the first conductor in step (4), such as reducing the electrical conductivity.

The second conductive material is, for example, a metal or alloy. These material are used by the turbidity solution or processed into the paste gel.

For example, a single metal was formulated as a liquid viscous material like a diluents of high volatility solvent with less residue material, mixed with some metal particles comprises a low melting point metal at least two, having a particle size of several 10 nm from a few microns (metal powder).

Alternatively, it may be impregnated (or is poured) to perfuse directly to the second conductive member which is in the liquid stage form by the above heating process of the melting point.

The particle size of the material constituting the second conductor is smaller than the size of the gap that is formed in the first conductive material is desirable.

The reason for this is because it is necessary “particle of the second conductor is looking into immersion sew the gap of the first conductor and porous” that.

In step (6) mentioned above, there will be the second conductive body is melted at a high temperature to “paste or solution” of the second conductive material.

By this step, (both are brought into close contact without voids hopefully) the second conductive material wherein is disposed in a gap of the first conductive material a porous, increasing the conductivity and mechanical strength is achieved.

In such a melting process, wherein the first conductive material is not melted, that only material which constitutes the second conductive material is melted is necessary.

For example, if composed of tungsten as the first electrical conductor, second conductor Should be composed of indium, and 160° C. is the setting temperature. This case is the preferred case indium particles in close contact to the periphery of the tungsten particles.

In step (7) mentioned above, the surface of the main surface of the substrate or plate-like structure is smoothed. In step (6) is completed step mentioned above, does not constitute the same plane (a second main surface and the first principal surface) or the first main surface, the surface of the through electrode becomes uneven.

The heat treatment step of forming a first conductive member or the second conductor to the heating state of the surface area of the through electrode in (the first main surface and the second major surface) or the first main surface is preferred. Some smoothing process use

a technique such as polishing such protrusions. In addition, and if the conductor is disposed on the bottom surface of the hole, when it is adhered to a glass plate (which is the side opposite to the filling-side) and the second main surface side, and only the first main surface smoothing is required.

Furthermore, the possibility of through hole via electrode region in the first principal surface becomes concave state, the electrical connection with the through hole via electrode becomes difficult because of the high gap, that you avoid this state is preferable. Sometimes, in order to avoid such a state is repeated a plurality of times (step (6) and (4)) the heat treatment step (the step (5) and (3)) filling step described above.

### Effect of the Invention

According to the method of manufacturing the same and this writing way the through via/the buried via electrode material and such electrode structure of the present invention can be formed completely, as compared to the electrode forming method of the various conventional process, without requiring expensive equipment, in a short time relatively dense metal electrode without minimum hollow possible without reliability level down, due to the difference in thermal expansion coefficient, and configure the embedded electrode embedded in the through/no degradation of signal transmission characteristics supported by its small conductivity.

It is possible to avoid the high temperature treatment process on over 230° C. in the step of forming electrodes, as a method of device wafer-temperature processing is not possible circuit is already formed (semiconductor substrate), it is effective, because it does not contain any high-temperature heat treatment at 300° C. or the manufacturing process of the through via/the buried via electrode material and such electrode structure in this way, it does not involve (including degradation) characteristic change of the device that is already configured to (e.g. a silicon wafer) some substrate or plate-like structure.

Further, or high integration capable for conductivity of the through via/the buried via electrode material and such electrode structure reducing the electrode size make it possible for high speed signal transfer and a large current pass by avoiding these large current and high speed signal missing former, moreover to reduce the manufacturing cost together possible.

### BRIEF DESCRIPTION OF THE DRAWINGS

FIG. 1A shows the diagram of the manufacturing process of the through via/the buried via electrode material and such electrode structure according to a first exemplary embodiment of the present invention.

FIG. 1B shows a diagram of some manufacturing process of the through via/the buried via electrode material and such electrode structure according to a first exemplary embodiment of the present invention as the continuation of FIG. 1A.

FIG. 2A is a diagram showing a manufacturing process of the through via/the buried via electrode material and such electrode structure according to a second exemplary embodiment of the present invention.

FIG. 2B is a diagram showing a manufacturing process of the through via/the buried via electrode material and such electrode structure according to the second embodiment of the present invention as a continuation of FIG. 2A.

FIG. 3 is a diagram showing a manufacturing process of the through via/the buried via electrode material and such electrode structure according to a third exemplary embodiment of the present invention.

FIG. 4 shows a conventional manufacturing method of the through via/the buried via electrode.

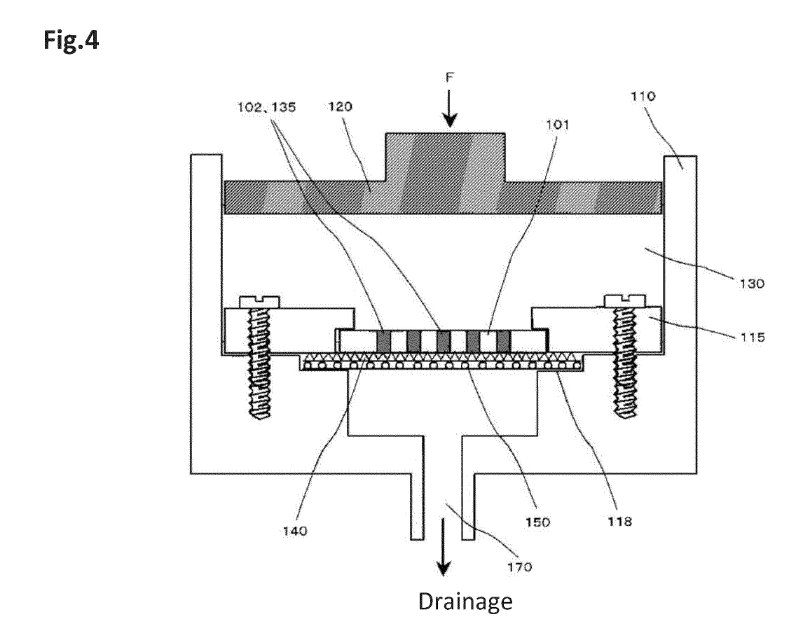

FIG. 5 shows the through hole via electrode conventional production method.

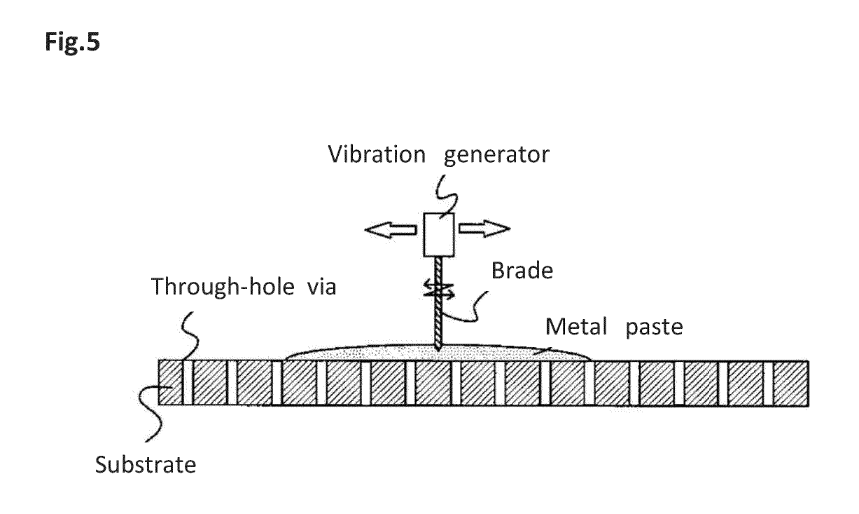

FIG. 6 is a diagram explains the illustrating of the bonding conditions and interconnecting state for some conductive material particles (powder) together in the manufacturing method of the through via/the buried via electrode material and such electrode structure according to one exemplary embodiment of the present invention.

### DESCRIPTION OF THE PREFERRED EMBODIMENTS

Preferred embodiments of the present invention will be described with reference to the drawings. However, it is possible to carry out in many different modes that the present invention can be modified in various modes and details thereof without departing from the spirit and scope of the present invention, readily by those skilled in the art is understood.

Accordingly, the present invention is not to be construed as being limited to the description of the present exemplary embodiment. In the following description, the same reference numerals are given to portions having the same or equivalent parts, and a description thereof will be omitted.

### First Embodiment

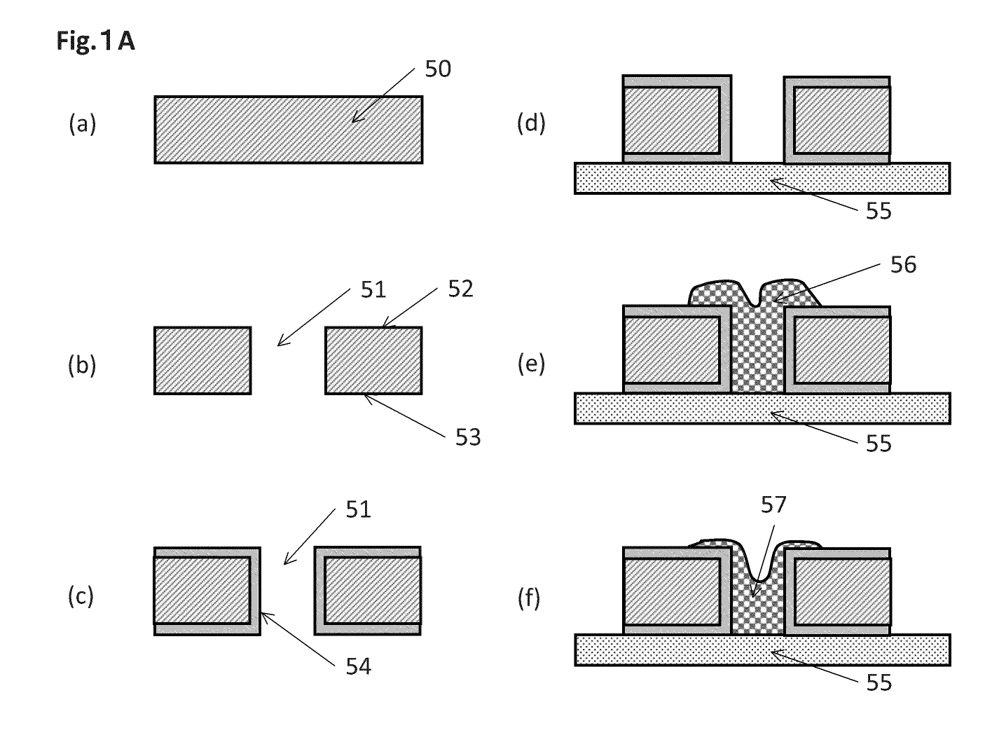

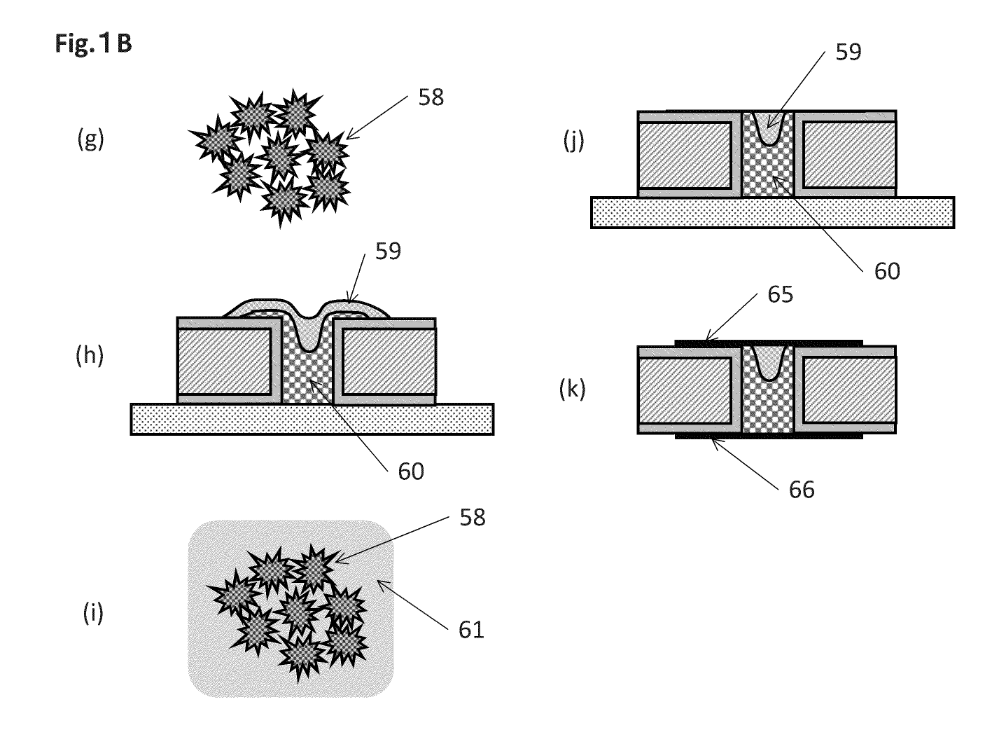

FIG. 1A and FIG. 1B show steps of manufacturing process of the through hole via electrodes according to a first exemplary embodiment of the present invention.

First, preparing some substrate or plate-like structure body 50 as shown in FIG. 1A (a). For example, a substrate or plate-like structure 50 is configured from a circuit board or a semiconductor wafer something like these.

Next, as shown in FIG. 1A (b), the etching process following a well known patterning technology, the through hole via 51 is formed in a substrate or plate-like structure 50. The through hole 51 penetrates up to 53 (the main surface of the lower in this case) from the second main surface 52 (the main surface of the top in this case) of the first main surface 50 plate-like structure.

This etching step, wet etching with an acid, such as dry etching using reactive gas is utilized. The inner diameter of the through (hole) via 51 is the size of 100 μm from several μm.

Next, as shown in FIG. 1A (c), the insulating layer 54 is formed, attached to the inner wall of the through hole via 51. This is because having a conductive substrate or plate-like structure 50.

However, if the substrate or plate-like structure 50 does not have electrical conductivity, the insulating layer 54 is not necessary. The formation of the insulating layer 54, a well-known method (such as film forming method utilizing a chemical reaction) CVD or thermal oxidation is used.

Insulating layer 54, depending on the production methods, but also formed on the second major surface 53 and first major surface 52 generally.

Subsequently, as shown in FIG. 1A (d), on the second main surface 53 of the substrate or plate-like structure 50, a support plate 55 which consists of a glass is disposed in close contact. Support plate 55 has a role to close the bottom portion of the through hole 51.

Thereafter, as shown in FIG. 1A (e), the first conductor is formed inside the through hole 51. To be more specific, metal particles, particles of the alloy, or particles, semiconductor particles or metal compounds, a first conductor, one of the conductive particles are coated dissimilar material to an inorganic material or organic it is formed by filling the through hole 51, a paste or a solution 56 containing a first conductive material consisting of at least one.

This filling, a well-known method such as screen printing and micro pipette is used.

As an example of the paste 56, or solution to be used here, (which is a conductive particles different material is coated on inorganic material) particulate matter tungsten coated with indium or the like is volatilized in a proportion of 85 wt % which is a paste that is opacity in solvent. For example, the particle size of the particulate matter are 0.5 μm from 0.3 μm. Constituents of the paste, the content and the solvent is not limited to the examples listed as examples.

Then, by heat treatment at a given temperature the paste 56 or solution, volatile solvent of 56 in paste or solution is dissipated, through-hole 51 is only (fine group of tungsten) fine group of 56 in paste or solution is deposited to. Thus, the deposited layer 57 shown in FIG. 1A (f) is formed.

Deposition conditions of the deposition layer 57, different (weight by volume, for example) configuration component of the paste 56 or solution, but as a result of the heat treatment, the volume is reduced in general. Further, it may also be deposited along (a region that is closed by the support plate 55) the bottom wall and the inner wall of the through hole 51, and the deposition conditions is filled (that is deposited over the entire inside of the through hole 51 may be). FIG. 1A to (f), the state of being formed deposited layer 57 over the entire inside of the through-hole 51 is shown.

FIG. 1B is a (g), a state in which particulates are deposited is shown conceptually. It FIG. 1B in (g), a large number of ultrafine particles are gathered, the particle size is in fine particles 58 from 0.5 μm 0.3 μm is shown. Gap is present between the particles 58 are gathered, therefore, the deposited layer 57 is made porous.

Next, as shown in FIG. 1B (h), the second conductor is formed in the through hole 51. To be more specific, a paste or a solution 59 containing a second conductive material consisting of an alloy or a metal is filled in the through hole 51.

As the organic solvent to formulate a paste or solution 59, ester alcohol, terpineol, pine oil, butyl carbitol acetate, butyl carbitol, carbitol, Park roll is preferred.

These solvents attack of the resist is low, and there is provided a volatilizable at relatively low temperatures even (50° C. below), drying after coating is because easier. Among them, Perchloroethylene (Tetrachloroethylene) is particularly preferable, since it is possible to dry at room temperature.

This filling, and penetration while fill the void with the deposition layer 57 of porous paste 59 or solution as “something like the reaching to the completely filling stage”. 60 FIG. 1B in (h), 59 paste or solution of the second conductive material indicating “the completely filling stage” in the deposition layer. If one example of a Code 59 or solution, and the like paste (52% indium, 48% tin) indium alloy, particulate matter constitutes the particles from particle size 0.05 μm 0.03 μm.

The mixing ratio of the organic solvent and metal powder of the metal paste is preferably 80˜99.9 wt % of metal powder, 1 to 20 wt % organic solvent. If this mixing ratio, prevents aggregation of the metal powder, since it become possible to supply of filler adequately.

The forming process, for example, is as follows. The through hole 51 which gave the insulating layer 54, and then applying and filling the paste 56 first conductive material (metal), making, drying, evaporation deposition.

Then, the substrate or plate-like structure 50 get the removing the oxide film from the residues of the solvent on the surface of the fine particles of the paste 56 which have the dried deposition of the paste 56 of the first conductive material full filled in the through hole 51, by processing in N2 atmosphere containing a reducing agent H2 of about 2%, at a temperature of 150˜230° C. of the heat treatment. By this way of solid phase sintering, the electrode structure porous is obtained.

Table 1 shows some typical formulation example of the pastes 56 about the constituents of the paste 56, the content, such as solvents, it is not limited to those illustrated here, of course.

TABLE 1

| Melting | | | |
|---|---|---|---|
| Point (° C.) | Sn | Bi | In |
| 78.8 | 17.3% | 57.5% | 25.2 |
| 117 | 48% | — | 52% |
| 138 | 42% | 58% | — |

Subsequently, by heat treatment in the volatile solvent with dissipated (about 120° C. in the case of indium-based alloy) to a predetermined temperature a paste 59 solution or indium alloy melts and so becomes the second conductor.

At this stage, the deposition layer 60 is formed as if the sintered second conductor is in close contact with the gap of the first conductor. In order to perform a complete filling of the second conductor, and a state without heat treatment is performed in a vacuum atmosphere, the second conductive material to flow into all areas of the deposited layer 57 of porous (so-called the “nest” it) is preferred, it may not always so.

FIG. 1B (i) shows schematically a detailed configuration of the deposited layer 60 when the complete filling of such were made. FIG. 1B in (i), the indium-based alloy 61 which has been melted is filled the void region 58 between the particles is shown.

In consideration of the performance of the coating machine, coating speed, the deposition density, etc., in coordination solid content ratio of (diluent ratio) and the grain size of the fine particles of the 59 in the paste or solution, it can be easily handled. The preferred machine

is a relatively inexpensive jet dispenser. Depending on the performance of model selection, number of iterations of the application is different. If it is general specification, it takes 2 iterations generally.

The formation process for example I shall be as follows. Whereas the plate-like structure 50 which is formed deposited layer 57 into the through hole 51, is coated with a second conductive metal paste 59 of the second metal so as to cover the deposition layer 57. Then, the heat-treated at a temperature of 150° C. in a vacuum environment a plate-like structure 50, thereby impregnating the second metal to the porous deposition layer 57.

In the above description, shows a method of using a paste comprising a second conductive material, but in the case of the low melting point metal such as indium alloy, 57 deposited porous layer (first conductor) and the alloy was melted there is also a method of pouring in, to penetrate the void regions molten state.

As the paste 59 of the second conductive metal, preferably solids particle size 30 nm, of 85 wt % as a selectable Paste. (Sn-17.3%, Bi-57.5%, In-25.2%, Melting point 78.8° C.). See Table 1)

The formation process of this case, for example, should be selected as follows. The through hole 51 processed the insulating layer 54, then the paste 56 filling with the first conductive material (metal), after that process finished, the evaporation and drying process for the deposition are setting.

Then, in N2 atmosphere containing a reducing agent H2 of about 2%, and heat-treated at a temperature of 200° C., a substrate or plate-like structure 50 to dry deposit of the paste 56 of the first conductive material is filled in the through hole 51, next step will be the removing the oxide film and then the residue material of the solvent on the surface of the particle first conductive material (metal) and (paste 56). Thus, by solid phase sintering, the electrode aggregates porous is obtained.

FIG. 1B (j) shows a view taken planarized (protrusions) portion formed on the first major surface 52, where the portion formed on the first major surface 52 of the 60 deposition layer, and the solution or filled part (convex portion with paste 59 (as said before, heat treatment step made the solid state).

Such planarization process is carried out in a well-known technique such as (the glossing process has a combination of mechanical polishing and chemical reactions) CMP polishing and mechanical polishing.

Depending on the shape of the deposition layer and the paste was solidified, may recess is generated in the central portion of the deposited layer 60 on the side of the first major surface 52. This recess should not occur preferably.

If a recess depth of μm order, never affect the electrical wiring pattern formed on the surface of the first major surface 52.

Finally, as shown in FIG. 1B (k), the second main surface 53 and first major surface 52 and 50 plate-like structure, to form respectively 66 and electric wiring layer 65. the through hole via electrode is completed (in this case, interposer) the substrate or plate-like structure 50 by the steps described above.

### Second Embodiment

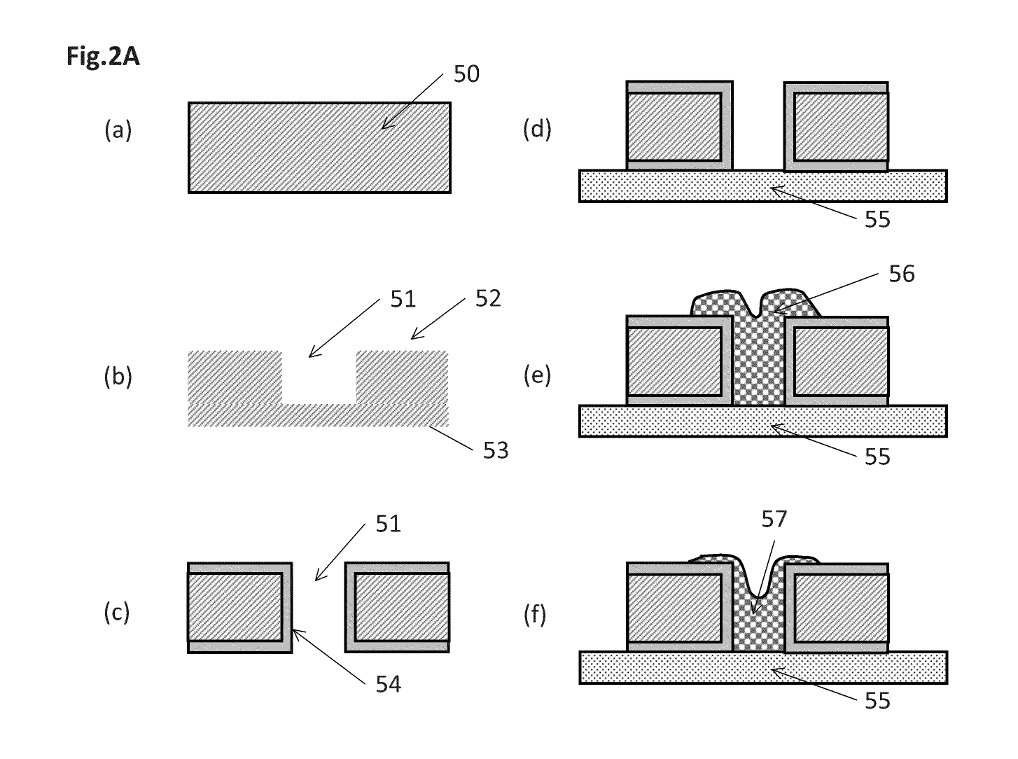

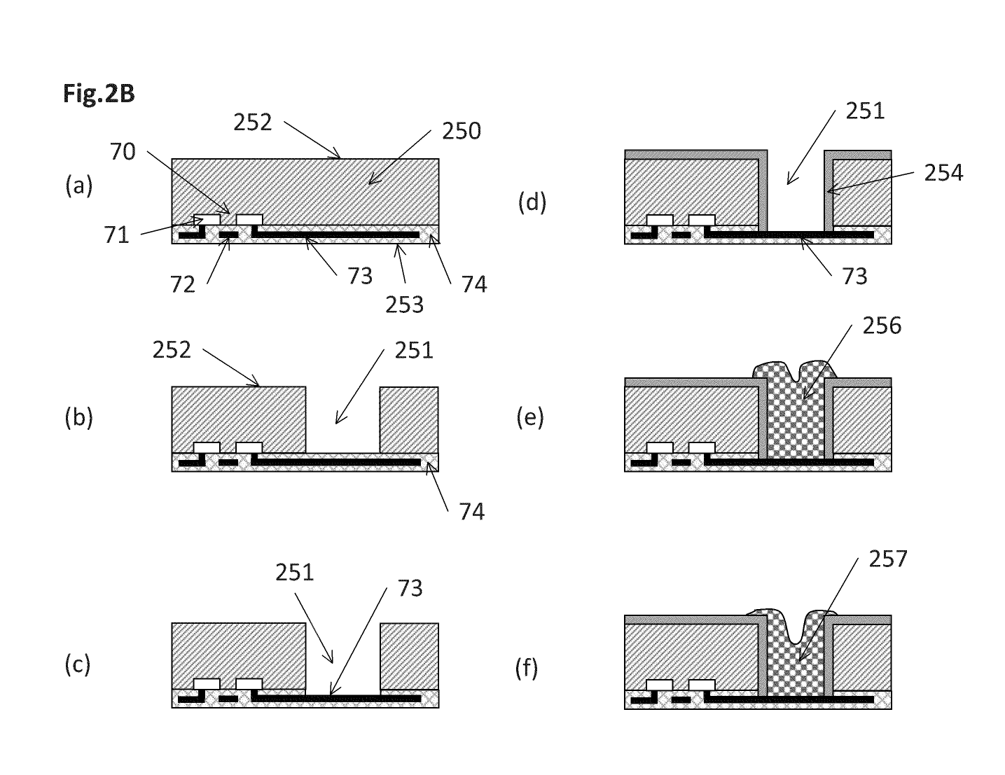

FIG. 2A and FIG. 2B show a process of manufacturing the through electrodes according to a second exemplary embodiment of the present invention.

First, as shown in FIG. 2A (a) a semiconductor wafer substrate or plate-like structure 250 should be prepared.

On the side, the transistor 70 is fixed on the second major surface 253 (the surface of the lower side in the figure) of the substrate or plate-like structure250.

Transistor 70 respectively forms the source and drain at the diffusion layer 71 and the gate electrode 72.

73 is a wiring layer to draw the potential of the diffusion layer 71, disposes an insulating layer 74 (generally that is the oxide film), together with the gate electrode 72.

Next, as shown in FIG. 2A (b), the hole 251 is formed in the etching step following patterning techniques known in the art.

In detail, the etching is completed in a state in which by a method such as reactive ion etching, holes drilled from the first major surface 252 side, the insulating film of the second major surface 253 side is exposed.

The inner diameter of the “hole” is the number 100 μm from several μm.

Next, as shown in FIG. 2A in (c), due to reactive ion etching acid in (HF) gas atmosphere, by hydrofluoric etching a first main surface 252 side of 74 the insulating layer to expose the wiring layer 73.

Next, as shown in FIG. 2A (d), to form an insulating layer 254 on the first major surface 252 and an inner wall of the hole 251. At this time, the insulating layer 254 is formed on the surface (bottom) surface of the wiring layer 73 which is exposed, it is removed by a known method.

By the process described above, the “hole conductor is disposed on the bottom surface” is formed.

Subsequently, as shown in FIG. 2A (e), the first conductor is formed inside of the hole 251.

To be more specific, metal particles, particles of the alloy, or particles, semiconductor particles or metal compound, the first consists of at least one of the conductive particles are coated dissimilar member to member of inorganic or organic into the hole 251, 256 “paste or solution” containing one conductive material to fill.

This filling, a well-known method such as micro pipette and screen printing should be used.

One example of the paste 256 or this solution, there is a paste particulate matter tungsten coated with indium-turbidity volatile solvent in a proportion of 85 wt %, the particulate matter is 0.5 μm of diameter 0.3 μm is a particle. Constituents of the paste 256, content, such as the solvent or solution is not limited to those illustrated. Subsequently, by heat treatment at a predetermined temperature a paste 256 or solution, the volatile solvent is dissipated only (metal particles) is deposited into the hole 251 particles of tungsten, and a first conductor (FIG. 2A is shown as deposited layer 257 (f)).

The different (weight by volume, for example) spectrograms of the paste 256 or solution, but the deposition conditions can also be good deposited along (a region where the wiring layer 73 is exposed) the bottom wall and the inner wall of the hole portion 251. Alternatively, over the entire inside of the hole 251 deposited may be filled. FIG. 2A to (f), a state of the deposited paste 256 or solution over the entire inside is shown.

FIG. 2 B (g) conceptually shows the deposition layer 257 is deposited and formed paste or solution 256.

That in FIG. 2B (g), in the deposition layer 257, the particle size is in the particles 258 from 0.5 μm 0.3 μm particulate matter many have gathered is shown. Gap exists between this nanoparticles gathered, therefore, the deposition layer 257 is made porous.

Subsequently, as shown in FIG. 2B (h), the second conductor is formed into the hole 251. To be more specific, a paste or a solution 259 containing a second conductive material consisting of an alloy or a metal is filled into the hole 251.

The filling is made as “completely full filled” It has to penetrate while filling the gap of the deposited layer 257 of the porous.

The 260 shown in (h) FIG. 2B, paste or solution 259 indicates “completely full filled” the deposition layer.

An example of a paste or 259 solution includes a fine particle indium alloy(52% indium, 48% tin), the particle group constitutes a particle of 258 particle size from 0.05 μm 0.03 μm.

Constituents of the paste, the content and the solvent are not limited to those illustrated.

Subsequently, by heat treatment in the volatile solvent with dissipated (about 120° C. in the case of indium-based alloy) to a predetermined temperature a paste 259 solution or indium alloy melts and becomes the second conductor.

At this stage, it is to state as if it were sintered second conductor is in close contact with the gap of the first conductor. In order to perform a complete filling of the second conductor, and a state without heat treatment is performed in a vacuum atmosphere, the second conductive material flows into all areas of the deposited layer 257 of the porous (so-called the “nest” thing) is preferred, but not necessarily limited to this.

FIG. 2B (i) shows a conceptual configuration of the through electrode when the complete filling of such were made. In FIG. 2B (i), that the indium alloy 261 is melted is filled the perimeter of the particle 258 is shown.

Next, as shown in FIG. 2B in (j), a portion of the first main surface 252 of the 260 deposition layer that is filling up and heat-treated, so that the portion of the solution or the paste 259 (the solid state of a heat treatment) should be removed to flattened the some portion (convex portion) of the first main surface 252.

This planarization process is performed in a well-known technique such as (the glossing process has a combination of mechanical polishing and chemical reactions) CMP polishing and mechanical polishing

Incidentally, depending on the shape of the solution or the paste 259 (is in the solid state) deposition of the first one main surface 252 and layer 260 (through hole electrode), there may recesses is generated in central portion of sedimentary layer 260. This recess preferred not to be generated, If this is the recess a depth of about μm level, never have effects on the electrical wiring pattern to be formed on the surface of the first 1 main surface 252.

Finally, as shown in FIG. 2B (k), and forming an electrical interconnect layer 265 on the first main surface 252 of the 250 plate-like structure. By the above process, is completed (silicon integrated circuit in this case) structure through electrodes is embedded into the hole 251.

From the first major surface 252 to the second major surface 253 “electrode which is formed on the hole” described in the second embodiment, not “through” but, “most of the thickness of the 250 plate-like structure penetrates”.

Further, in the three-dimensional structure, since the electrical connection wires of the second major surface 253 side (electrode), the wiring of the first major surface 252 side and the (electrode), for convenience, is referred to as “through-electrode” are.

Accordingly, the present invention is the “through-electrode” electrode structure as described in the second exemplary embodiment is also included.

### Third Embodiment

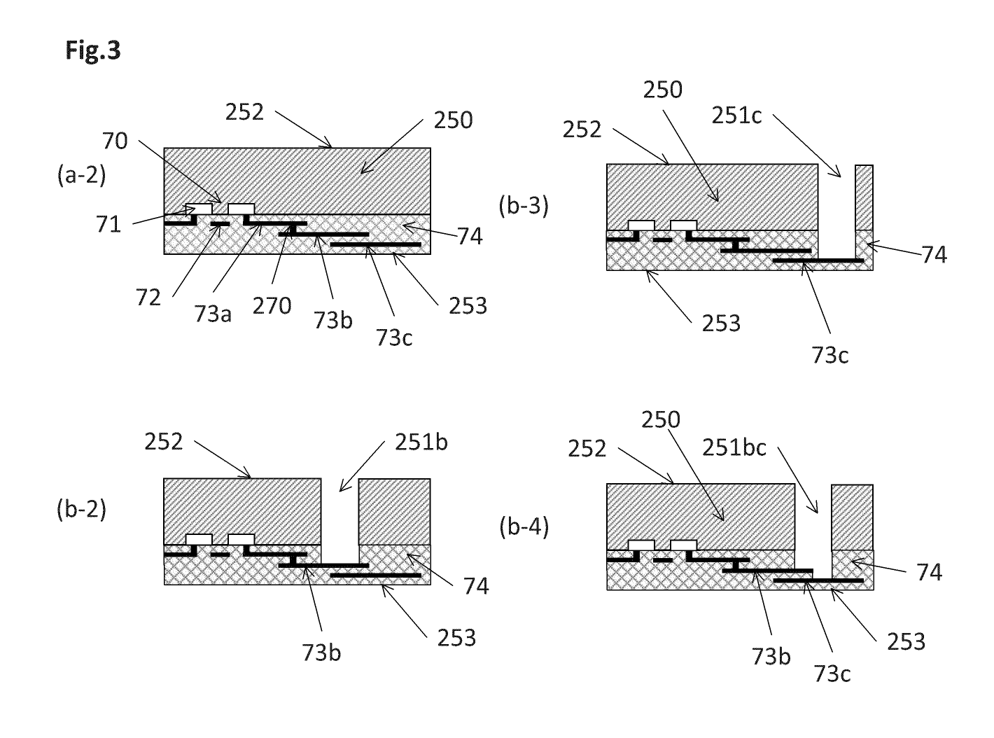

FIG. 3 shows the manufacturing process of the through electrode according to the third embodiment of the present invention. The present embodiment is a case of using a multilayer wiring in the second exemplary embodiment of the present invention. Thus, in FIG. 3, the same numbers as in FIGS. 2A and 2B show a second exemplary embodiment of the present invention, shows the same components.

First, as shown in FIG. 3 (a), to prepare a plate-like structure 250 which is a semiconductor wafer.

The plate-like structure 250, the side of the second main surface 253 of the 250 plate-like structure, the wiring layer 73a of the plurality, 73b, 73c is disposed inside the insulating layer 74.

Interlayer wiring 270 is disposed between the wiring layers (in the figure, the second layer 73b and the first layer 73a) and is connected electrically between the wiring layers adjacent to each other. A plurality of wiring layers such and interlayer wiring is often used in silicon integrated circuits.

Next, as shown in FIG. 3 (b), the hole portion 251b for forming through electrodes that reaches the wiring layer 73b of the second layer is formed. Then, similarly to the second embodiment described above, the through electrode is formed in the hole portion 251b.

In FIG. 3, the case of forming the through electrodes to the wiring layer 73b of the second layer is shown, the present invention is not limited thereto, the through electrodes formed on the wiring layer other layers are also possible. Hole 251c in the case of forming the through electrodes to the wiring layer 73c of the third layer is shown in FIG. 3 (c). Thus, a multilayer wiring structure, it is possible to form a through electrode wiring layer for any given.

In FIG. 3 (d), holes 251bc in the case of forming the through electrode common to both of the wiring layer 73c of the third layer and the wiring layer 73b of the second layer is shown.

When forming the through electrode configuration for such interlayer wiring 73c and the wiring layer 73b is simultaneously formed, it is possible to draw to the first major surface 252 side both these.

That is, it is possible to impart multiple functions through one electrode.

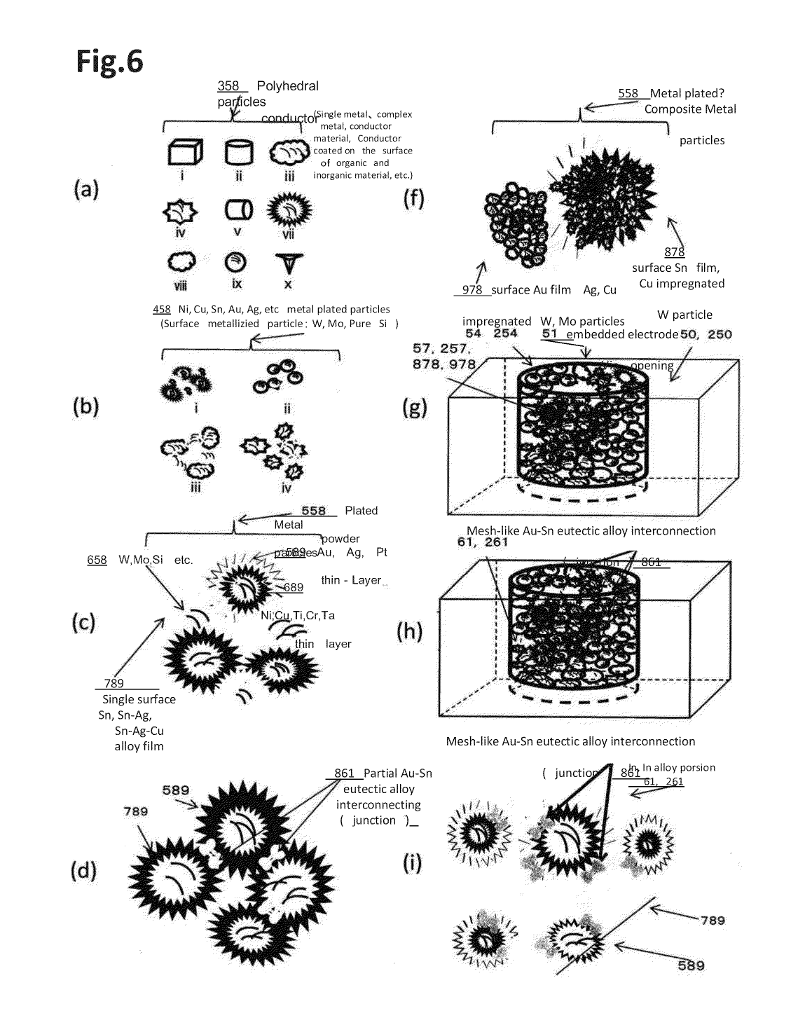

In the manufacturing method of the through via/the buried via electrode material and its structure according to one exemplary embodiment of the present invention, FIG. 6 is a diagram illustrating the bonding conditions conductive material particles (powder) together.

FIG. 6(a) shows a single metal-metal complex, conductor, the conductor surface coat organic and inorganic material ie an example of conductor particles 358 of the polyhedron.

FIG. 6 (b) shows an example of the metal particles 458, i.e., single metal and W, Mo, the Si, the ones whose surface is plated Ni, Cu, Sn, Au, Ag, etc.

FIG. 6 (c) shows an example of a plated metal particles 558, 589 represents Au,Ag and Pt coating film, 689 represents Ni, Cu, Ti, Cr, and Ta coating film, 789 shows the surface Sn single film coating, Sn—Ag alloy film, a Sn—Ag—Cu alloy film, 658 shows a metal particles W, Mo, and Si, and the like.

FIG. 6(d), shows a partial Au—Sn eutectic alloy joints 589,789,861.

FIG. 6 (f) shows an example of a plated metal particles 558, 878 shows the Sn surface layer of the W particles impregnated Cu, 978 shows the Au surface with Ag or Cu impregnated in to W or Mo particles.

FIG. 6 (g) and (h), shows the state of various particles in the interior of the embedded or buried electrode.

FIG. 6 (i) shows the internal structure of the mesh Au—Sn eutectic alloy junction or interconnection.

### (Physical Properties of the Conductive Material Used in the Present Invention)

Here, I will describe the physical properties of these materials. Are shown collectively in Table 2 the main physical constants.

TABLE 2

| | Thermal | | | |
|---|---|---|---|---|
| | Expansion | Volume | Thermal | Melting |
| | Coefficient | resistivity | Conductivity | Point |
| | (1/K) | (10 [symbol] Ω-m) | (w/m/K) | (° C.) |
| Tungsten | 4.5 | 5.28 | 173 | 3422 |
| Molybdenum | 4.8 | 5.34 | 138 | 2623 |
| Chrome | 4.9 | 12.5 | 94 | 1907 |
| Tin | 22 | 11.5 | 63 | 232 |
| Palladium | 11.8 | 10.5 | 72 | 1555 |
| Gold | 14.2 | 2.2 | 318 | 1064 |
| Copper | 23.1 | 2.8 | 237 | 660 |
| Silver | 13.4 | 6.9 | 91 | 1455 |
| Nickel | 16.5 | 1.68 | 401 | 1085 |
| Aluminum | 18.9 | 1.59 | 429 | 962 |
| Indium | 32.1 | 8.37 | 76 | 157 |
| Crystal | 2.3~3.4 | Depends on | 168 | 1412 |
| silicon | | impurities | | |

[symbol]

indicates data missing or illegible when filed

From Table 2, when a reference semiconductor wafer (single crystal silicon), the thermal expansion coefficient of tungsten is approximately 1.7 times, indium is about 12.3 times, the effect of internal stress due to the difference in thermal expansion coefficient person of the tungsten is small (assumed to correspond to reliability). Further, (conductivity greater smaller) volume resistivity of tungsten is lower than indium. Also here for indium lower thermal conductivity.

From these, by selected and indium as a second conductive material, is set larger than the volume of indium volume of tungsten inside the through electrode, the tungsten as the first conductive material, the conductive coefficient of thermal expansion and so it is possible to make clear that the effectively prevent characteristic degradation of those thermal expansion coefficient and conductivity rate effectively.

Furthermore, the melting point of indium is 157° C., since the extremely low than the melting point of tungsten, by heat-treating it after filled with pasty a second conductive material, it is melted only indium easily and around the tungsten particles is possible to cover all.

Further, it is also possible without processing into a paste, let flowing directly into the interior of the through electrode by heating and melting the indium and infiltrate. Even when adopting such a process, the highest temperature in the step is at 200° C. less, never deteriorate the properties of devices fabricated on the semiconductor wafer as described above.

In addition, (=Young's modulus is small) for soft, indium thermal expansion tungsten

There is also a possibility that the (volume increases) even if, indium can absorb the expansion.

For conductive material constituting the second conductor of the first conductor, there are many choices.

For example, it is possible to select the tin to the second conductor, the tungsten in the first conductor is also possible.

Thermal expansion coefficient of about 8.5 times greater when compared to a single crystal silicon and tin. It is approximately 1.3 times compared to indium volume resistivity of the tin.

Furthermore, the melting point is 232° C., which is a value higher than indium, but is acceptable range. Considering these figures, tin can be selected as the second conductive material.

That described above is when the conductive material is a single metal. However, not limited to this conductive material, or alloys of these different materials (such as tin and indium)

Out may be a conductive particle whose surface is coated with (such as tungsten).

In the first to third embodiments described above, it has been described as limiting the constituent material of the second conductor and the first conductor, but the present invention is not limited to the combinations described above.

It is the key to make clear the following matter because that the thermal expansion coefficient of the mentioned substrate or plate-like structure requirements for preventing the reliability degradation due to the difference in thermal expansion coefficient and the degradation of signal transmission characteristics due to the conductivity.

(1) the first conductor thermal expansion coefficient fix not to exceed three times to the above mentioned substrate or plate-like structure thermal expansion coefficient.
(2) the second conductive member, which is composed of a conductive material having a melting point not exceeding 300° C.,
(3) the second conductor volume does not exceed the volume of the first conductor.

If we satisfy these requirements, the material of the second conductor and the first conductor can be selected arbitrarily.

the present invention has been described above with reference to the accompanying drawings a preferred embodiment. The present invention is can be implemented in many different modes, which can be modified in various modes and details thereof without departing from the spirit and scope of the present invention will be readily understood by those skilled in the art.

Accordingly, the present invention is not to be construed as being limited to the description.

The invention allows to significantly improve the signal transmission characteristics and reliability of the through electrode. This improvement, placement of a high density through electrodes due to miniaturization of semiconductor manufacturing technology can be realized.

### INDUSTRIAL APPLICABILITY

Semiconductor field, and a method of manufacturing the embedded electrode structure embedded through/in accordance with the present invention, since an element basic techniques in a three-dimensional structure in particular, the present invention is not limited to embedded electrode embedded with the through electrode simply, these it is widely applicable to the sensor system (memory circuit, the arithmetic processing circuit, and drivers) and three-dimensional integrated circuits applications.

### DESCRIPTION OF CODES

50, 250 Substrate structure
51 Through(-hole) via
52, 252 First main surface
53, 253 Second major surface
54, 74, 254 Insulating layer
55 Support plate(Substrate)
56, 59, 256, 259 Solution medium or Paste
57, 60, 257, 260 Sedimentation, Sedimentary layers, Deposited Layer
61, 261 Metals or alloys
58, 258 particle object
65, 66, 73, 73a, 73b, 73c, 265 Wiring layer
70 Transistor
7 Diffusion layer
72 Gate electrode
251, 251b, 251c, 251bc Through-hole via or Hole
270 Intermediate layer wiring

1. The through via/the buried via electrode material and its structure having the feature of the porous first conductive material formed by being heat-treated which has the ahead step of filling them into the hole at least one disposed on the first main surface of the substrate or plate-like structure, and some penetration characterized in that a second conductor composed of a second conductive material to penetrate the cavity of the first conductor, the second conductive material is different from the first conductive material of embedded electrode structure.

2. According to claim 1, the through via/the buried via electrode material and its structure having the feature of metal particles, particles of the alloy, or particles, semiconductor particles or metal compounds, wherein the first conductive material is composed of at least one of the conductive particles are coated dissimilar member to member of inorganic or organic, and the metal particles, particles of the alloy particles of the metal compound, semiconductor particles, or, Winning, consists of at least one of the particles of the organic member having electrical conductivity, the second conductive material of said second conductive material is included and characterized in that it is different from the first conductive material.

3. According to claim 1, alternatively hole, minimum one, is included in the through via/the buried via electrode material and its structure having the feature characterized in that the conductor is disposed on the bottom surface of the hole portion of the at least one at least.

4. According to claim 1, the through via/the buried via electrode material and its structure having the first electrical conductor implantable through hole via characterized in that it has a thermal expansion coefficient that does not exceed three times the thermal expansion coefficient of the said substrate or plate-like structure electrode structure.

5. A method of manufacturing said the through via/the buried via electrode material and its structure having the feature of embedded through/forming the embedded electrode embedded or through electrode inside the opening of the semiconductor substrate,
a step of the opening of the semiconductor substrate, and dried by filling a paste or solution of the first metal to be aggregates of the electrodes,
a step of phase sintering the solid in an atmosphere containing a reducing gas, the semiconductor substrate the paste or solution of the first metal is filled into the opening, forming an electrode aggregate porous,
a step of applying a paste or solution of a second metal so as to cover the electrode aggregates,
by further comprising a step of heat-treated in a vacuum environment,
the said semiconductor substrate coated by the paste or solution of the second metal,
the said melted paste or solution of the said second metal, impregnating the electrode aggregate method of insertion electrode structure is embedded through.

6. According to claim 5, a method of manufacturing said the through via/the buried via electrode material and its structure having the feature of using the particle which size of the metal powder larger than any particle in the paste or solution of the second metal,
pastes or solutions of the first metal is a liquid viscous material and diluent volatile solvent, was prepared the metal powder having a particle size of 500 nm or less,
paste or solution of the second metal is a liquid viscous material which comprises a low melting point metal at least two kinds of particle size was prepared as a diluent volatile solvent metal powder of 30 nm or less.

7. According to claim 2, alternatively hole, minimum one, is included in the through via/the buried via electrode material and its structure having the feature characterized in that the conductor is disposed on the bottom surface of the hole portion of the at least one at least.

8. According to claim 2, the through via/the buried via electrode material and its structure having the first electrical conductor implantable through hole via characterized in that it has a thermal expansion coefficient that does not exceed three times the thermal expansion coefficient of the said substrate or plate-like structure electrode structure.

9. According to claim 3, the through via/the buried via electrode material and its structure having the first electrical conductor implantable through hole via characterized in that it has a thermal expansion coefficient that does not exceed three times the thermal expansion coefficient of the said substrate or plate-like structure electrode structure.
